(19) United States
(12) Patent Application Publication
(10) Pub. No.: US 2026/0118448 A1
(43) Pub. Date: Apr. 30, 2026

(54) POWER MODULE FOR VEHICLE INCLUDING HALL SENSOR AND MOTOR DRIVING APPARATUS INCLUDING THE SAME

(71) Applicants: HYUNDAI MOTOR COMPANY, SEOUL (KR); KIA CORPORATION, SEOUL (KR)

(72) Inventor: Suk Hyun Lim, Hwaseong-si (KR)

(73) Assignees: HYUNDAI MOTOR COMPANY, SEOUL (KR); KIA CORPORATION, SEOUL (KR)

(21) Appl. No.: 19/228,339

(22) Filed: Jun. 4, 2025

(30) Foreign Application Priority Data
Oct. 29, 2024 (KR) 10-2024-0149212
May 26, 2025 (KR) 10-2025-0068176

(51) Int. Cl. G01R 33/07; B60L 15/00; G01R 15/20; H02M 7/537; H05K 1/18

(52) U.S. Cl. CPC G01R 33/07; B60L 15/00; G01R 15/202; H02M 7/537; H05K 1/181; H05K 2201/10151

(57) ABSTRACT

A power module for a vehicle is provided. The power module includes a circuit board including an insulating layer and a first metal layer, a switching unit disposed on the circuit board, a lead frame disposed on one side of the circuit board, a signal lead disposed on the other side of the circuit board, and a Hall sensor arranged on the circuit board. The Hall sensor includes a sensing unit disposed to sense a magnetic field of a target pattern of the first metal layer and a magnetic shield providing magnetic shielding for at least a portion of a surface other than one surface of the sensing unit facing the target pattern.

### CROSS-REFERENCE TO RELATED APPLICATION(S)

This application claims benefit of priority to Korean Patent Application No. 10-2024-0149212 filed on Oct. 29, 2024 and Korean Patent Application No. 10-2025-0068176 filed on May 26, 2025, in the Korean Intellectual Property Office, the disclosures of which are incorporated herein by reference in their entirety.

### TECHNICAL FIELD

The present disclosure relates to a power module for a vehicle including a Hall sensor and a motor driving apparatus including the power module.

### BACKGROUND

Eco-friendly vehicles may include hybrid vehicles (HEVs), plug-in hybrid vehicles (HEVs), electric vehicles (EVs), fuel cell electric vehicles (FCEVs), and/or the like A power module of eco-friendly vehicles receives DC current from a high-voltage battery, inverts the received DC current into AC current, supplies the AC current to a motor, and controls the torque and rotational speed of the motor by adjusting the magnitude and phase of the AC current.

### SUMMARY

The current of the power module may be used to control at least one of the power module, the motor, and the battery. An aspect of the present disclosure is to provide a power module for a vehicle including a Hall sensor and a motor driving apparatus including the same, capable of reducing magnetic field noise when sensing the current of the power module to improve sensing accuracy or reducing energy loss and/or heat generation due to current sensing.

According to an aspect of the present disclosure, a power module for a vehicle includes a circuit board including an insulating layer and a first metal layer, a switching unit disposed on the circuit board, a lead frame disposed on one side of the circuit board, a signal lead disposed on the other side of the circuit board, and a Hall sensor arranged on the circuit board. The Hall sensor includes a sensing unit disposed to sense a magnetic field of a target pattern of the first metal layer, and a magnetic shield providing magnetic shielding for at least a portion of a surface other than a (e.g., one) surface of the sensing unit facing the target pattern.

A portion of the signal lead may be electrically connected to the switching unit through a portion of a signal pattern of the first metal layer, and another portion of the signal lead may be electrically connected to the Hall sensor through another portion of the signal pattern of the first metal layer.

The Hall sensor may further include a Hall sensor bonding wire electrically connecting the other portion of the signal pattern of the first metal layer to the sensing unit by bypassing the magnetic shield.

The power module may further include a switching unit bonding wire electrically connecting a high current pattern of the first metal layer to the switching unit, wherein the lead frame is electrically connected to the high current pattern of the first metal layer.

The first metal layer may further include a high current pattern electrically connected to the lead frame and a signal pattern electrically connected to the signal lead, and the target pattern of the first metal layer may be spaced apart from the high current pattern.

At least a portion of the magnetic shield may be disposed on the target pattern.

The Hall sensor may further include an insulating support portion disposed between the target pattern and the magnetic shield, and a bonding portion bonding the sensing unit to the target pattern.

The Hall sensor may further include an insulating support portion arranged between the target pattern and the magnetic shield, and a portion of the insulating support portion may be disposed between the sensing unit and the target pattern.

The Hall sensor may further include an insulating support portion disposed on (or in) a pattern, different from the target pattern, in the first metal layer, and the magnetic shield may be disposed on the insulating support portion so as not to overlap the sensing unit in a direction in which the sensing unit and the target pattern face each other.

The Hall sensor may further include a sub-substrate disposed between the sensing unit and the magnetic shield and electrically connected to the sensing unit, and the sub-substrate may be supported by a pattern, different from the target pattern, on the first metal layer so that the sensing unit is spaced apart from the target pattern.

The Hall sensor may further include a sub-substrate disposed between the sensing unit and the target pattern and electrically connected to the sensing unit, and a Hall sensor bonding wire electrically connecting the signal pattern of the first metal layer to the sub-substrate.

At least a portion of the magnetic shield may be disposed on the sub-substrate, and the Hall sensor bonding wire may be connected to the outside of a region in which the magnetic shield is disposed on the sub-substrate.

A combined structure of the magnetic shield and the sub-substrate may seal the sensing unit.

The magnetic shield may surround a side surface of the sensing unit, a lower surface of the sensing unit may face the target pattern, and the magnetic shield may cover an upper surface of the sensing unit.

The power module may further include a case accommodating the circuit board, wherein the case has a U-shape and is open in a direction in which the circuit board faces the sensing unit.

The power module may further include a case accommodating the circuit board, wherein the Hall sensor further includes a ground bonding wire electrically connecting the magnetic shield to the case.

The power module may further include an encapsulant accommodated by the case, wherein the Hall sensor further includes a Hall sensor bonding wire electrically connecting the signal pattern of the first metal layer to the sensing unit, and the encapsulant is in (e.g., direct) contact with the circuit board, the magnetic shield, and the Hall sensor bonding wire.

The magnetic shield may have a cantilever shape.

The Hall sensor may further include a bonding portion bonding the sensing unit and to the magnetic shield.

The Hall sensor may further include a magnetic shield support portion supporting the magnetic shield so that the magnetic shield is separated from the first metal layer, and the magnetic shield support portion may have a cantilever shape.

The Hall sensor may further include a magnetic shield support portion supporting the magnetic shield so that the magnetic shield is spaced apart from the first metal layer, and the magnetic shield support portion may surround a side surface of the sensing unit, a lower surface of the sensing unit may face the target pattern, and the magnetic shield support portion may cover an upper surface of the sensing unit.

The Hall sensor may further include the magnetic shield support portion supporting the magnetic shield so that the magnetic shield is spaced apart from the first metal layer, and the sensing unit may be disposed on the magnetic shield support portion so as to be spaced apart from the first metal layer, and a portion of the magnetic shield support portion may be positioned between the magnetic shield and the sensing unit.

The Hall sensor may further include the magnetic shield support portion supporting the magnetic shield so that the magnetic shield is spaced apart from the first metal layer, and a bonding portion bonding the sensing unit to the magnetic shield support portion, wherein a portion of the magnetic shield support portion may be positioned between the magnetic shield and the sensing unit.

The Hall sensor may further include the magnetic shield support portion supporting the magnetic shield so that the magnetic shield is spaced apart from the first metal layer, and the magnetic shield support portion may be formed of an insulating material.

The Hall sensor may further include an insulating support portion stacked (or laminated) on the sensing unit, and the magnetic shield may be stacked on the insulating support portion.

The Hall sensor may further include a sub-substrate disposed between the sensing unit and the target pattern and electrically connected to the sensing unit, and the sensing unit may be disposed between the sub-substrate and the insulating support portion, and the insulating support portion may be disposed between the sensing unit and the magnetic shield.

The sensing unit may include a sensing integrated circuit (IC) configured to sense a magnetic field of the target pattern of the first metal layer; and a sensing terminal electrically connecting the sensing IC to the first metal layer.

The switching unit may include a first switching unit, a second switching unit, and a third switching unit, wherein the first switching unit may include a plurality of first semiconductor chips, the second switching unit may include a plurality of second semiconductor chips, and the third switching unit may include a third semiconductor chip.

The first switching unit may be disposed in a central portion of the circuit board, the second switching unit may be disposed on an outside of the first switching unit on the circuit board, and the third switching unit may be disposed on the outside of the first switching unit on the circuit board.

According to another aspect of the present disclosure, a motor driving apparatus includes a power module for a vehicle, as described herein. The power module may be a three-phase power module. In each phase of the three-phase power module, the first switching unit includes a 1-1 switching element and a 1-2 switching element and corresponds to one leg of a first inverter, the second switching unit includes a 2-1 switching element and a 2-2 switching element and corresponds to one leg of a second inverter, and one end of the third switching unit is connected between a first node between the 1-1 switching element and the 1-2 switching element and a second node between the 2-1 switching element and the 2-2 switching element and constitutes a portion of a changeover switch.

### BRIEF DESCRIPTION OF DRAWINGS

The above and other aspects and features of the present disclosure may be understood from the following detailed description and the accompanying drawings.

FIG. 1 is a side view illustrating a power module for a vehicle according to an embodiment of the present disclosure.

FIG. 2 is a side view illustrating a power module for a vehicle according to an embodiment of the present disclosure.

FIG. 3 is a side view illustrating a power module for a vehicle according to an embodiment of the present disclosure.

FIG. 4 is a side view illustrating a power module for a vehicle according to an embodiment of the present disclosure.

FIG. 5 is a plan view illustrating a power module for a vehicle according to an embodiment of the present disclosure.

FIG. 6 is a circuit diagram illustrating a power module for a vehicle and a motor driving apparatus including the same according to an embodiment of the present disclosure.

FIGS. 7, 8, 9, 10, 11, and 12 are respective side views illustrating various examples of a Hall sensor that may be included in a power module for a vehicle according to an embodiment of the present disclosure.

### DETAILED DESCRIPTION

While the present disclosure may be modified in various ways and take on various alternative forms, specific embodiments thereof are shown in the drawings and described in detail below. However, it should be understood that there is no intent to limit the present disclosure to the particular forms disclosed, but on the contrary, the present disclosure covers (e.g., all) modifications, equivalents, and alternatives falling within the spirit and scope of the present disclosure.

Although the terms “first,” “second,” and the like may be used herein to describe various elements, these elements should not be limited by these terms. These terms are used to distinguish one element from another. For example, a first element could be termed a second element, and a second element could similarly be termed a first element without departing from the scope of the present disclosure. As used herein, the term “and/or” includes (e.g., any and all) combinations of one or more of the associated listed items.

The terms used herein to describe embodiments of the present disclosure is not intended to limit the scope of the present disclosure. The articles “a,” and “an” are singular in that they have a single referent, however the use of the singular form in the present document should not preclude the presence of more than one referent. Elements of the present disclosure referred to in the singular may be one or more, unless the context indicates otherwise. It may be further understood that the terms “comprise,” “comprising,” “include,” and/or “including,” when used herein, provide the presence of stated features, numbers, steps, operations, elements, and/or components but do not preclude the presence or addition of one or more other features, numbers, steps, operations, elements, components, and/or groups thereof.

Unless defined in a different way, (e.g., all) the terms used herein including technical and scientific terms have meanings to which the present disclosure pertains. Such terms as defined in dictionaries should be construed to have the same meanings as those of the contexts of the related art, and unless defined in the application, they should not be construed to have ideally or excessively formal meanings.

In this specification, vehicles refer to a variety of vehicles that move transported objects, such as people, animals, or goods, from a starting point to a destination. These vehicles are not limited to vehicles that run on roads or tracks.

Hereinafter, embodiments of the present disclosure will be described with reference to the accompanying drawings.

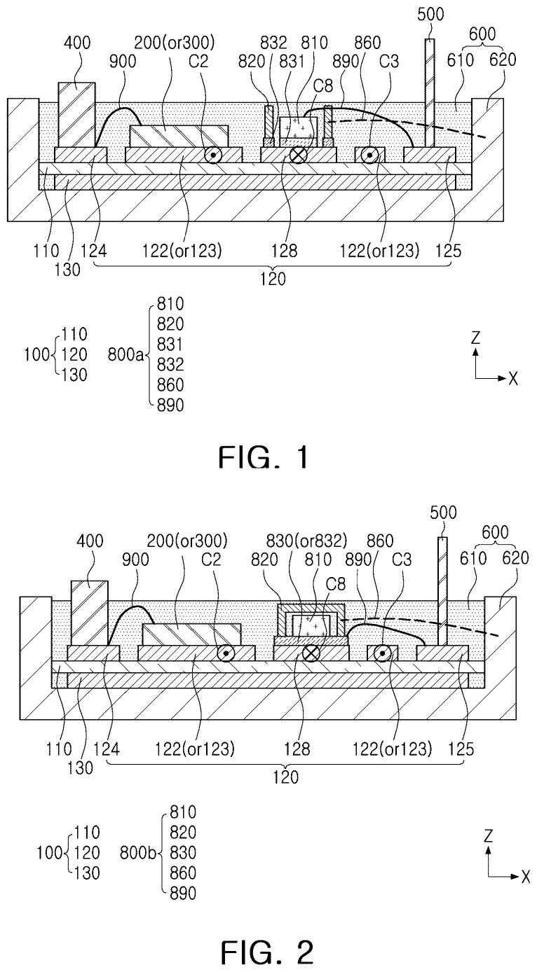

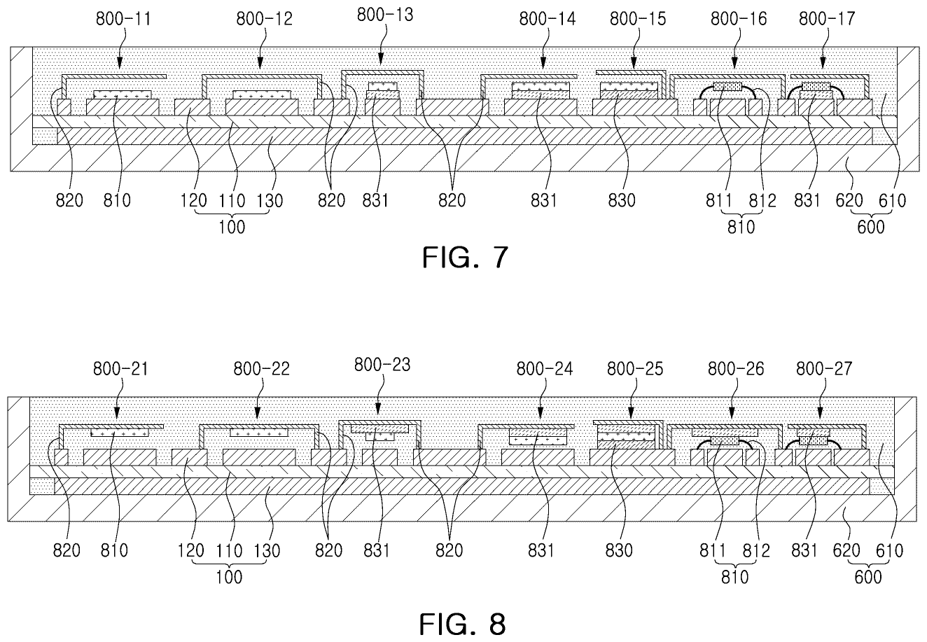

FIGS. 1, 2, 3, and 4 are side views each illustrating a power module for a vehicle according to an embodiment of the present disclosure, and FIG. 5 is a plan view illustrating a power module for a vehicle according to an embodiment of the present disclosure. Referring to FIGS. 1, 2, 3, 4, and 5, a power module for a vehicle according to an embodiment of the present disclosure may include a circuit board 100, a switching unit 200 or 300, a lead frame 400, a signal lead 500, and a Hall sensor 800 (800a, 800b, 800c, or 800d).

The circuit board 100 may include an insulating layer 110 and a first metal layer 120 and may further include a second metal layer 130 depending on the example embodiment (e.g., design). For example, the circuit board 100 may be implemented as an active metal brazed (AMB) substrate or a direct bonded copper (DBC) substrate, the insulating layer 110 may be implemented as a ceramic layer, and each of the first and second metal layers 120 and 130 may be implemented as a copper layer, but the present disclosure is not limited thereto.

A portion of the insulating layer 110 may overlap the first metal layer 120 in a vertical direction (a Z-direction), and the remaining portion of the insulating layer 110 may not overlap the first metal layer 120 in the vertical direction (the Z-direction). For example, the first metal layer before patterning may be formed to overlap the (e.g., entire) region of the insulating layer 110, a portion of the first metal layer before patterning may be removed by a patterning method (e.g., a photolithography method), the first metal layer 120 after patterning may include a plurality of patterns (e.g., a pattern 122 or 123, a high current pattern 124, a signal pattern 125, and a target pattern 128), and the plurality of patterns may provide a plurality of electrical connection paths for the switching unit 200 or 300.

For example, the second metal layer 130 may dissipate heat generated in the switching unit 200 or 300 and the first metal layer 120 to the outside of the power module and may be electrically separated from the first metal layer 120 by the insulating layer 110. Alternatively, the second metal layer 130 may provide a ground for the switching unit 200 or 300 and may be electrically connected to a portion of the pattern of the first metal layer 120 through a conductive via of the insulating layer 110. Although not shown, a cooling channel for cooling the power module may be in contact with a lower surface of the second metal layer 130.

The switching unit 200 or 300 may be disposed on the circuit board 100. For example, the switching unit 200 or 300 may include a semiconductor device, such as an insulated gate bipolar transistor (IGBT) or a metal oxide semiconductor field effect transistor (MOSFET), may further include a diode, and may be implemented as at least one of an integrated circuit, a chip, and a die. The switching of the switching unit 200 or 300 may refer to switching between an ON state and an OFF state of the semiconductor device.

The switching unit 200 or 300 may receive a control signal from an external source of the power module through the signal lead 500 and may switch the ON/OFF state of the semiconductor device according to the control signal. Depending on the switching of the switching unit 200 or 300, the switching unit 200 or 300 may invert a DC current input through the lead frame 400 into an AC current.

The lead frame 400 may be disposed on one side of the circuit board 100 (e.g., disposed to be slanted from the center of the circuit board 100 in a −X-direction). For example, the lead frame 400 may include an N-type electrode 410, a P-type electrode 420, and an output electrode 430.

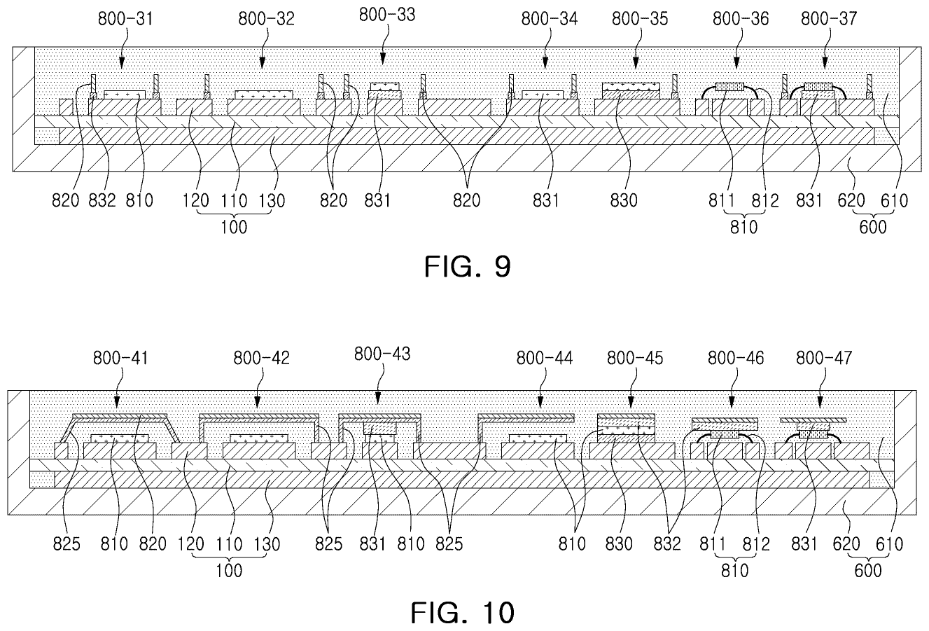

The DC current provided from the battery may be input to the switching unit 200 or 300 through the N-type electrode 410 and the P-type electrode 420, and the AC current inverted by the switching unit 200 or 300 may be output through the output electrode 430 and output to a motor (2 of FIG. 6).

For example, the number of output electrodes 430 may be three, and the three output electrodes 430 may be electrically connected to a first switching unit (200 of FIG. 5), a second switching unit (300 of FIG. 5), and a third switching unit (700 of FIG. 5).

For example, the number of N-type electrodes 410 may be two, and the P-type electrode 420 may be disposed between the two N-type electrodes 410. This structure may be defined as an N-P-N busbar structure. In an example embodiment, depending on the design, the number of P-type electrodes 420 may be two, and the N-type electrode 410 may be disposed between the two P-type electrodes 420. This structure may be defined as a P-N-P busbar structure. Accordingly, the overall parasitic inductance of the lead frame 400 may be reduced.

For example, compared to the output electrode 430, the N-type electrode 410 and the P-type electrode 420 may be disposed closer to the first switching unit (200 of FIG. 5). Accordingly, an electrical distance between the battery and the first switching unit (200 of FIG. 5) may be shortened, so that energy efficiency may be improved. Compared to the transmission energy efficiency of AC current, the transmission energy efficiency of DC current may have a greater impact on the overall energy efficiency of the power module, and thus, the reduced electrical distance between the battery and the first switching unit (200 in FIG. 5) may have a significant impact on the overall energy efficiency of the power module.

The signal lead 500 may be disposed on the other side of the circuit board 100 (e.g., disposed to be slanted from the center of the circuit board 100 in a +X-direction). For example, a portion of the signal lead 500 may be electrically connected to the switching unit 200 or 300 through a portion of the signal pattern 125 of the first metal layer 120, and another portion of the signal lead 500 may be electrically connected to the Hall sensor 800 (800a, 800b, 800c, and 800d) through another portion of the signal pattern 125 of the first metal layer 120. Accordingly, the signal lead 500 provides a path for transmitting a control signal to the switching unit 200 or 300 and also provides a path for externally providing a sensing value of the Hall sensor 800 (800a, 800b, 800c, and 800d).

The magnitude of the control signal and sensing value that may be transmitted through the signal lead 500 may be less than the magnitude of the DC current provided from the battery and may be less than the magnitude of the AC current provided to the motor (2 of FIG. 6). Accordingly, the overall dimensions (e.g., a width, a pitch) of the signal lead 500 may be less than the overall dimensions of the lead frame 400, but are not limited thereto.

The Hall sensor 800 (800a, 800b, 800c, and 800d) may be disposed on the circuit board 100 and sense a magnetic field according to a current C8 of a target pattern 128 of the first metal layer 120 to sense the current C8. That is, the Hall sensor 800 (800a, 800b, 800c, and 800d) may sense the current C8 in a non-contact manner by sensing the magnetic field formed to surround the current C8 of the target pattern 128 even without contacting the target pattern 128.

Therefore, compared to other methods (e.g., a method of sensing current through a resistor shunt-connected to the target pattern 128), the energy loss and/or heat generation due to the sensing of current C8 by the Hall sensor 800 (800a, 800b, 800c, and 800d) may be smaller. Therefore, the power module for a vehicle according to an embodiment of the present disclosure may further improve the overall energy efficiency and reduce the overall heat generation.

In addition, the Hall sensor 800 (800a, 800b, 800c, and 800d) may be disposed on the circuit board 100 and built into the power module for a vehicle according to an embodiment of the present disclosure. Compared to a structure in which the Hall sensor is disposed outside the power module, a structure in which the Hall sensor 800 (800a, 800b, 800c, and 800d) is disposed on the circuit board 100 may reduce the effective volume of the power module, may reduce the cost of disposing the Hall sensor, and may reduce external magnetic field noise.

In addition, the Hall sensor 800 (800a, 800b, 800c, and 800d) may include a sensing unit 810 and a magnetic shield 820. The sensing unit 810 may be disposed to sense the magnetic field of the target pattern 128 of the first metal layer 120. The magnetic shield 820 may provide magnetic shielding for at least a portion of a surface other than one surface (e.g., a lower surface) of the sensing unit facing the target pattern 128.

Accordingly, the Hall sensor 800 (800a, 800b, 800c, and 800d) may reduce the magnetic field noise (e.g., the magnetic field noise according to current C2 or C3 of the pattern 122 or 123) within the power module, thereby further improving the current C8 sensing accuracy.

For example, the sensing unit 810 may include a structure in which four resistance elements are connected in a Wheatstone bridge manner, may receive current power through two of the four nodes between the four resistance elements, and may output a voltage of the other two of the four nodes. The voltage output by the sensing unit 810 may be determined by the magnetic field of the sensing unit 810, and thus may be a sensing value. For example, the sensing unit 810 may be implemented as a bare die or an integrated circuit.

For example, the magnetic shield 820 may include a magnetic material (e.g., ferrite, iron, and/or the like) with high permeability, so that the magnetic field directed toward the magnetic shield 820 may be attenuated or reflected.

The Hall sensor 800 (800a, 800b, or 800d) may further include a Hall sensor bonding wire 890 electrically connecting another portion of the signal pattern 125 of the first metal layer 120 to the sensing unit 810. The sensing unit 810 may transmit a sensing value externally through the Hall sensor bonding wire 890 and the signal pattern 125.

The power module for a vehicle may further include a switching unit bonding wire 900 electrically connecting the high current pattern 124 of the first metal layer 120 to the switching unit 200 or 300, and the lead frame 400 may be electrically connected to the high current pattern 124 of the first metal layer 120.

For example, the Hall sensor bonding wire 890 and/or the switching unit bonding wire 900 may include a material having high conductivity, ductility, and malleability, such as gold (Au), but is not limited thereto.

For example, the target pattern 128 of the first metal layer 120 may be a portion of the high current pattern 124. Alternatively, the target pattern 128 of the first metal layer 120 may be spaced apart from the high current pattern 124.

The power module for a vehicle according to an embodiment of the present disclosure may include a module frame 600 forming the overall shape of the power module for a vehicle, and the module frame 600 may include a case 620 and an encapsulant 610. That is, the power module for a vehicle may further include the case 620 accommodating the circuit board 100 and may further include the encapsulant 610 accommodated by the case 620.

For example, the case 620 may have a U-shape in which the circuit board 100 is open in a direction (e.g., a +Z-direction) facing the sensing unit 810. The U-shape of the case 620 may accommodate a power module structure having one circuit board 100. However, in the present disclosure, the number of circuit boards 100 is not limited to one. In an example embodiment, depending on the design, the power module structure may have two or more circuit boards 100.

When there is one circuit board 100, the circuit board 100 may cover (e.g., only) the lower side of the switching unit 200 or 300 and the Hall sensor 800 (800a, 800b, 800c, and 800d) and may not cover the upper side of the switching unit 200 or 300 and the Hall sensor 800 (800a, 800b, 800c, and 800d), and the volume occupied by the circuit board 100 and the cost of implementing the circuit board 100 may be reduced. The external magnetic field noise of the power module may be directed to the Hall sensor 800 (800a, 800b, 800c, and 800d) from the upper side of the power module, but the magnetic shield 820 may block the external magnetic field noise of the power module.

For example, the case 620 may have a hexahedral shape with an open upper surface (e.g., like a cap) and may be implemented with a material having high durability and/or thermal conductivity (e.g., metal material, gold (Au), silver (Ag), copper (Cu), iron (Fe), graphite, graphene, and/or the like), or may be implemented with a material (e.g., polymer, ceramic, and/or the like) resistant to harsh external environments.

In an example embodiment, according to the design, the case 620 may be implemented as a cooling channel for cooling the power module and may provide grounding to the switching unit 200 or 300 and/or the Hall sensor 800 (800a, 800b, or 800d). For example, the Hall sensor 800 (800a, 800b, or 800d) may further include a ground bonding wire (860) electrically connecting the magnetic shield 820 to the case 620.

The encapsulant 610 may (e.g., directly) contact the circuit board 100, the magnetic shield 820, and the Hall sensor bonding wire 890 and may protect the interior of the power module as a whole by encapsulating the circuit board 100, the magnetic shield 820, and the Hall sensor bonding wire 890. For example, the encapsulant 610 may include a molding material, such as epoxy molding compound (EMC) or may include silicone gel, but is not limited thereto. For example, when there is one circuit board 100, the encapsulant 610 may include silicone gel to (e.g., efficiently) accommodate the U-shaped case 620, but is not limited thereto.

Referring to FIG. 1, at least a portion of the magnetic shield 820 may be disposed on the target pattern 128. The Hall sensor 800a may include an insulating support portion 832 disposed between the target pattern 128 and the magnetic shield 820 and may include a bonding portion 831 bonding the sensing unit 810 to the target pattern 128. Accordingly, the Hall sensor 800a and the magnetic shield 820 may be arranged adjacent to the target pattern 128 while preventing or minimizing adverse effects (e.g., damage due to heat and electrical short) due to the high current C8 of the target pattern 128.

For example, the insulating support portion 832 may include an insulating material and, depending on the design, may include an adhesive material (e.g., an adhesive polymer, and/or the like). Accordingly, the magnetic shield 820 may be supported by the insulating support portion 832 and fixed to a specific position of the target pattern 128.

For example, the magnetic shield 820 may have a wall shape (e.g., completely) surrounding a side surface of the sensing unit 810. The Hall sensor 800a may further include a Hall sensor bonding wire 890 electrically connecting another portion of the signal pattern 125 of the first metal layer 120 to the sensing unit 810 by bypassing the magnetic shield 820. For example, the structure bypassing the magnetic shield 820 may include a structure clearing the magnetic shield 820 or a structure penetrating through a hole (including a boundary insulation treatment) that may be formed in the magnetic shield 820.

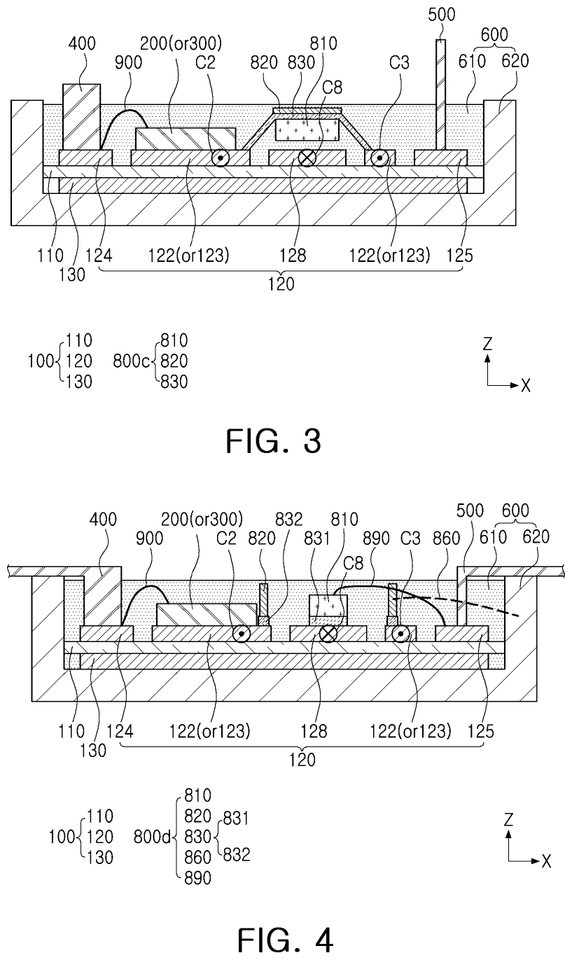

Referring to FIG. 2, a lower surface of the sensing unit 810 may face the target pattern 128, and the magnetic shield 820 may cover an upper surface of the sensing unit 810. Accordingly, the magnetic shield 820 may (e.g., more effectively) block magnetic field noise directed toward the sensing unit 810. For example, the magnetic shield 820 may have a U-shape in which the sensing unit 810 is open in a direction (e.g., a −Z-direction) toward the circuit board 100, and may have a hexahedral shape with an open bottom (e.g., like a cap).

The Hall sensor 800b may further include an insulating support portion 832 disposed between the target pattern 128 and the magnetic shield 820, and a portion (e.g., the center) of the insulating support portion 832 may be disposed between the sensing unit 810 and the target pattern 128. For example, the insulating support portion 832 may be implemented as a layer including an insulating material.

Alternatively, the Hall sensor 800b may include a sub-substrate 830 disposed between the sensing unit 810 and the target pattern 128 and electrically connected to the sensing unit 810 and may further include a Hall sensor bonding wire 890 electrically connecting the signal pattern 125 of the first metal layer 120 to the sub-substrate 830. Accordingly, since the Hall sensor bonding wire 890 may not be (e.g., directly) connected to the sensing unit 810, the stability or freedom of implementation of the Hall sensor bonding wire 890 may further increase.

For example, the sub-substrate 830 may have a structure in which at least one metal layer and at least one insulating layer are alternately stacked, such as a printed circuit board. The at least one metal layer may have a form that does not block between the sensing unit 810 and the target pattern 128. Accordingly, the sensing unit 810 may sense current of the target pattern 128 through the sub-substrate 830.

For example, at least a portion of the magnetic shield 820 may be disposed on the sub-substrate 830, and the Hall sensor bonding wire 890 may be connected to the outside of a region in which the magnetic shield 820 is disposed in the sub-substrate 830. For example, the at least one metal layer may be electrically connected to the sensing unit 810 and electrically connected to the Hall sensor bonding wire 890 through a lower side of the magnetic shield 820. Accordingly, the shape of the magnetic shield 820 may be implemented without considering the Hall sensor bonding wire 890, and thus, the freedom of implementation of the magnetic shield 820 may further increase.

A combined structure of the magnetic shield 820 and the sub-substrate 830 may seal the sensing unit 810, and the magnetic field noise directed to the sensing unit 810 may be (e.g., more effectively) blocked. For example, the sub-substrate 830 may be in direct contact with the U-shaped edge of the magnetic shield 820.

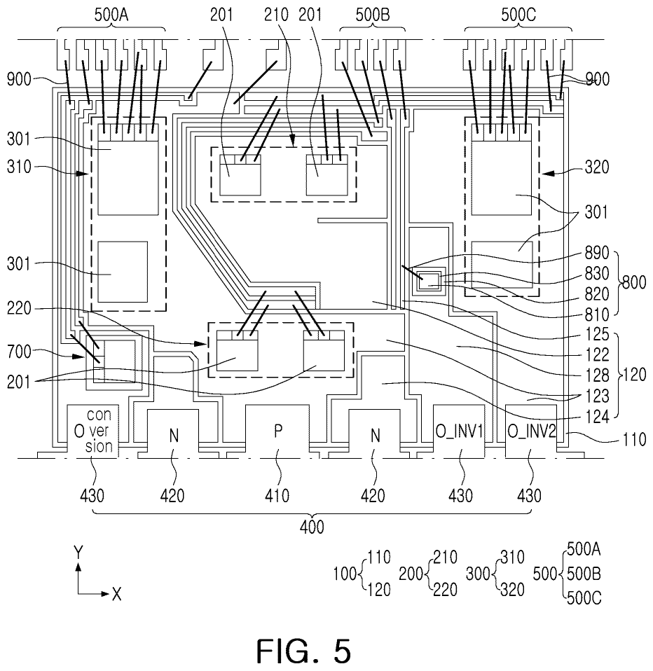

Referring to FIG. 3, the Hall sensor 800c may further include the sub-substrate 830 disposed between the sensing unit 810 and the magnetic shield 820 and electrically connected to the sensing unit 810, and the sub-substrate 830 may be supported by a pattern (e.g., the patterns 122 and 123, the signal pattern 125, the high current pattern 124) different from the target pattern 128 in the first metal layer 120 so that the sensing unit 810 is separated from the target pattern 128.

For example, the sub-substrate 830 may have a bridge shape, the sensing unit 810 may be mounted on the lower surface of the sub-substrate 830, and the magnetic shield 820 may have a form stacked on the upper surface of the sub-substrate 830. For example, the sub-substrate 830 may be implemented as a flexible printed circuit board.

In an example embodiment, depending on the design, the magnetic shield 820 may not cover a side surface of the sensing unit 810 and may block the external magnetic field of the power module from being directed to the sensing unit 810. For example, the metal layer within the sub-substrate 830 may be (e.g., concentratedly) arranged at the edge portion of the sub-substrate 830 to block the magnetic field noise (e.g., the magnetic field noise according to the current C2 or C3 of the patterns 122 or 123) within the power module from being directed to the sensing unit 810, but is not limited thereto.

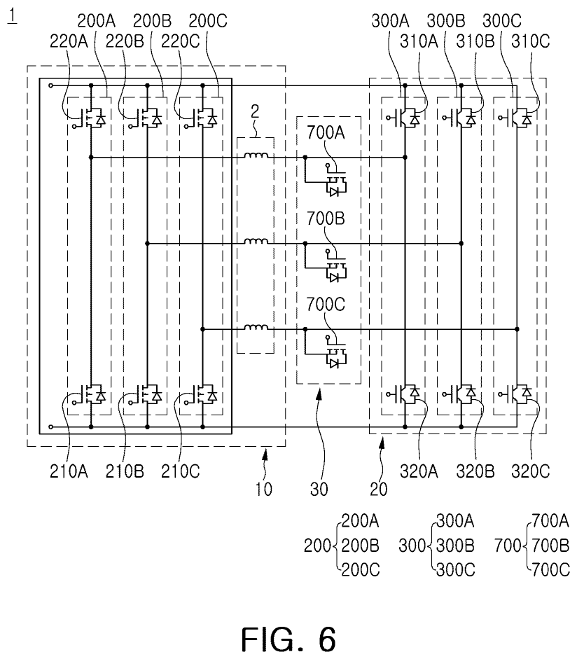

Referring to FIG. 4, the Hall sensor 800d may further include an insulating support portion 832 disposed on a pattern (e.g., the patterns 122 and 123, the signal pattern 125, and the high current pattern 124) different from the target pattern 128 in the first metal layer 120. The magnetic shield 820 may be disposed on the insulating support portion 832 not to overlap the sensing unit 810 in a direction (e.g., the Z-direction) in which the sensing unit 810 and the target pattern 128 face each other. The magnetic shield 820 of FIG. 4 may also block magnetic field noise according to the current C2 or C3 of the pattern 122 or 123.

Each of the lead frame 400 and the signal lead 500 may extend to opposing sides (e.g., in the X-direction) of the power module to be supported by the U-shaped edge of the case 620. For example, when the case 620 is formed of a metal material, the U-shaped edge of the case 620 may be subjected to an insulating coating or an insulating surface treatment.

FIG. 5 is a plan view illustrating a power module for a vehicle according to an embodiment of the present disclosure, and FIG. 6 is a circuit diagram illustrating a power module for a vehicle and a motor driving apparatus including the same according to an embodiment of the present disclosure.

Referring to FIG. 5, the switching unit may include a first switching unit 200, a second switching unit 300, and a third switching unit 700, and the first switching unit 200 may include a plurality of first semiconductor chips 201, the second switching unit 300 may include a plurality of second semiconductor chips 301, and the third switching unit 700 may include a third semiconductor chip.

For example, the first switching unit 200 and the third switching unit 700 may be implemented with a SiC (silicon carbide) chip, and the second switching unit 300 may be implemented with a Si chip. Since the second switching unit 300 may be (e.g., wholly selectively) turned off, the second switching unit 300 may be implemented with a relatively low-performance Si chip. Since the frequency of use of the first switching unit 200 and the third switching unit 700 may be relatively higher than that of the second switching unit 300, the first switching unit 200 and the third switching unit 700 may be implemented with relatively high-performance SiC (silicon carbide) chips. The semiconductor types of each switching element described herein are examples according to the present disclosure, and are not limited thereto, and various types of semiconductors may be applied.

Referring to FIG. 6, a three-phase power module for a vehicle (corresponding to A, B, C of the reference numerals) are provided, and in each phase of the three-phase power module, the first switching units 200A, 200B, and 200C may include 1-1 switching elements 210A, 210B and 210C and 1-2 switching elements 220A, 220B, and 220C but may correspond to one leg of a first inverter 10, the second switching units 300A, 300B, and 300C may include 2-1 switching elements 310A, 310B, and 310C and 2-2 switching elements 320A, 320B, and 320C but may correspond to one leg of a second inverter 20, and one end of the third switching units 700A, 700B, and 700C may be connected between a first node between 1-1 switching elements 210A, 210B, and 210C and 1-2 switching elements 220A, 220B, and 220C and a second node between 2-1 switching elements 310A, 310B, and 310C and 2-2 switching elements 320A, 320B, and 320C and may form a portion of a changeover switch 30.

A motor driving apparatus for a vehicle may receive DC current of a high-voltage battery provided in an electric vehicle, invert the input DC current into AC current, and output the AC current to a motor 2 to operate the motor 2.

The motor driving apparatus may be provided with an inverter (e.g., the first inverter 10) including a plurality of switching elements, and in example embodiment (e.g., depending on the design), two inverters (e.g., the first inverter 10 and the second inverter 20) may be provided to (e.g., efficiently) drive the motor 2.

Among the two inverters, the first inverter 10 is (e.g., constantly) operated, and when the motor 2 uses (e.g., requires) high output, the second inverter 20 may be operated together with the first inverter 10. The first inverter 10 and the second inverter 20 are connected to each other, and the changeover switch 30 may be provided to be turned on to provide a Y connection between each phase winding of the motor 2 when only the first inverter 10 is operated, and to be turned off when the second inverter 20 is also operated.

In order to operate the three-phase motor 2 in the motor driving apparatus described herein, each of the first inverter 10 and the second inverter 20 includes six switching elements, and the switching elements are divided into top phase elements (e.g., the 1-2 switching elements 220A, 220B, and 220C and/or 2-1 switching elements 310A, 310B, and 310C) and bottom phase elements (e.g., 1-1 switching elements 210A, 210B, and 210C and/or 2-2 switching elements 320A, 320B, and 320C), and the top phase elements and bottom phase elements connected in series form one leg, and these three legs are each connected to the motor 2 to operate the motor 2.

The frequency of use of the first switching unit 200 may be higher than that of the second switching unit 300, and the number of switching elements of the first switching unit 200 may be greater than that of the third switching unit 700. Therefore, compared to the second switching unit 300 and the third switching unit 700, the first switching unit 200 may have a greater effect on the overall energy efficiency of the power module.

For example, the first switching unit 200 may be disposed in the center of the circuit board 100, the second switching unit 300 may be disposed on the outside of the first switching unit 200 on the circuit board 100, and the third switching unit 700 may be disposed on the outside of the first switching unit 200 on the circuit board 100. Accordingly, an electrical length between the lead frame 400 and the first switching unit 200 may be shortened, and the parasitic impedance may also be reduced due to the simplification of the electrical path between the lead frame 400 and the first switching unit 200. The reduction in the electrical length may increase energy efficiency, and the increase in the energy efficiency of the first switching unit 200 may improve the overall energy efficiency of the power module. In addition, this structure may minimize an insulation distance of the signal lead 500 and may reduce the overall size of the power module.

For example, the 1-2 switching element 220 of the 1st switching unit 200 and the 2-2 switching element 320 of the 2nd switching unit 300 may be formed with the same potential difference, and by arranging the 1-2 switching element 220 of the first switching unit 200 and the 2-2 switching element 320 of the second switching unit 300 adjacently, an insulation distance other than a (e.g., required) insulation distance of the signal lead 500 may be eliminated, thereby reducing the size of the circuit board 100.

The third switching unit 700 may be disposed adjacent to the 2-1 switching element 310 of the second switching unit 300. The third switching unit 700 may be formed to have the same potential difference as that of the 2-1 switching element 310 of the second switching unit 300, and since the third switching unit 700 and the 2-1 switching element 310 of the second switching unit 300 are arranged adjacently, the insulation distance, other than the (e.g., required) insulation distance of the signal lead 500, may be eliminated, thereby reducing the size of the circuit board 100.

Since the potential difference is the same as the 1-2 switching element 220 of the first switching unit 200, the signal lead may be disposed adjacent to the 1-2 switching element 220 of the first switching unit 200 to eliminate the insulation distance, other than the (e.g., required) insulation distance of the signal lead 500, thereby reducing the size of the circuit board 100.

One end of the third switching unit 700 may be connected between the motor 2 and the second switching unit 300 and the other end thereof may be connected to the lead frame 400 so as to be interconnected outside the power module, thereby providing a Y-connection for each winding of the motor 2 when turned on.

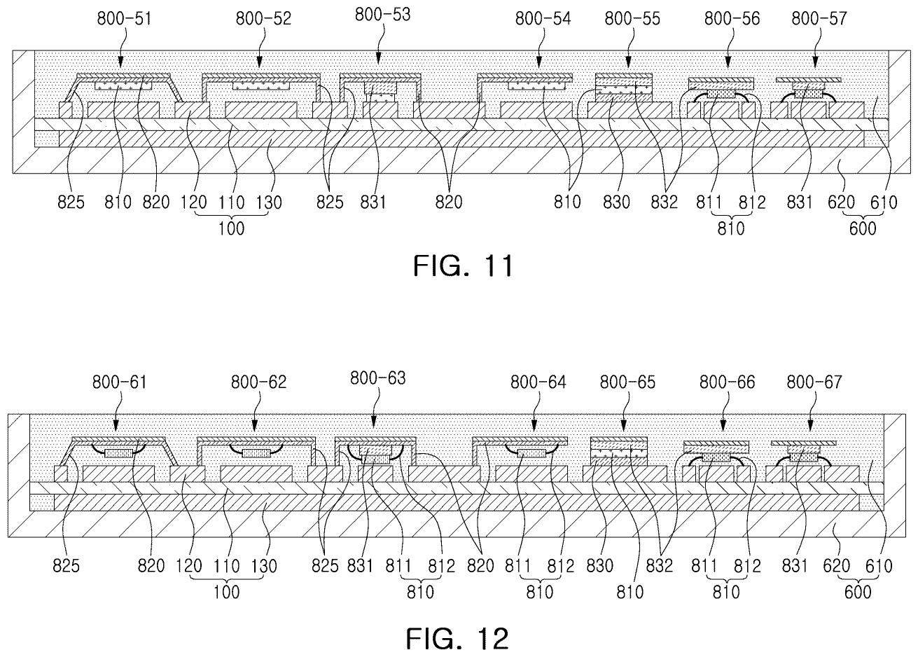

FIGS. 7 to 12 illustrate various examples of a Hall sensor that may be included in a power module for a vehicle according to an embodiment of the present disclosure, and the structure (e.g., the switching unit, the lead frame, the signal lead) other than the Hall sensor of the power module for a vehicle illustrated in FIGS. 1 to 4 is omitted.

Referring to FIGS. 7 to 12, Hall sensors 800-11, 800-12, 800-13, 800-14, 800-15, 800-16, 800-17, 800-21, 800-22, 800-23, 800-24, 800-25, 800-26, 800-27, 800-31, 800-32, 800-33, 800-34, 800-35, 800-36, 800-37, 800-41, 800-42, 800-43, 800-44, 800-45, 800-46, 800-47, 800-51, 800-52, 800-53, 800-54, 800-55, 800-56, 800-57, 800-61, 800-62, 800-63, 800-64, 800-65, 800-66, and 800-67 may include a sensing unit 810 disposed to sense a magnetic field of a target pattern of the first metal layer 120 and a magnetic shield 820 providing magnetic shielding for at least a portion of a surface (e.g., an upper surface and/or a side surface) of the sensing unit 810 other than a surface thereof (e.g., a lower surface) facing the target pattern.

Referring to FIGS. 7 and 8, the magnetic shield 820 may provide magnetic shielding for at least a portion of the side surface and the upper surface of the sensing unit 810. Referring to FIG. 9, the magnetic shield 820 may provide magnetic shielding for at least a portion of the side surface of the sensing unit 810. Referring to FIGS. 10 to 12, the magnetic shield 820 may provide magnetic shielding for the upper surface of the sensing unit 810.

Referring to FIGS. 7, 9, and 10, the sensing unit 810 may be disposed on one surface (e.g., the upper surface) of the target pattern of the first metal layer 120. Referring to FIGS. 8, 11, and 12, the sensing unit 810 may be disposed on one surface (e.g., a lower surface) of the magnetic shield 820.

Referring to FIGS. 7 and 8, the magnetic shield of the Hall sensors 800-11, 800-14, 800-15, 800-17, 800-21, 800-24, 800-25, and 800-27 may have a cantilever shape. One end of the cantilever may be connected (e.g., bonded, fused) to the first metal layer 120, and the other end of the cantilever may be spaced apart from the first metal layer 120.

Referring to FIG. 8, the Hall sensor 800-23, 800-24, 800-25, 800-26, and 800-27 may further include a bonding portion 831 bonding the sensing unit 810 to the magnetic shield 820. For example, the bonding portion 831 may include an adhesive material or an insulating material (which may have weak adhesiveness depending on the design). For example, the bonding portion 831 including the insulating material may be stacked on one surface of the magnetic shield 820, and the sensing unit 810 may be stacked on one surface of the bonding portion 831 including the insulating material.

Referring to FIGS. 10 to 12, the Hall sensors 800-41, 800-42, 800-43, 800-44, 800-51, 800-52, 800-53, 800-54, 800-61, 800-62, 800-63, and 800-64 may further include a magnetic shield support portion 825 supporting the magnetic shield 820 so that the magnetic shield 820 is spaced apart from the first metal layer 120. For example, the magnetic shield support portion 825 may be formed of an insulating material or a conductive material having lower permeability than permeability of the magnetic shield 820, but is not limited thereto. Due to the magnetic shield support portion 825, the size of the magnetic shield 820 may be reduced, and thus, the cost for manufacturing the Hall sensor may be reduced.

For example, the magnetic shield support portion 825 of the Hall sensors 800-41, 800-42, 800-43, 800-51, 800-52, 800-53, 800-61, 800-62, and 800-63 may surround the side surface of the sensing unit 810, the lower surface of the sensing unit 810 may face the target pattern of the first metal layer 120, and the magnetic shield support portion 825 may cover the upper surface of the sensing unit 810. For example, the magnetic shield support portion 825 may have a bridge shape or a polyhedral shape, but is not limited thereto.

For example, the magnetic shield support portion 825 of the Hall sensors 800-44, 800-54, and 800-64 may have a cantilever shape. Compared to the magnetic shield 820, the magnetic shield support portion 825 may include a wider variety of materials, so the magnetic shield support portion 825 may be more easily implemented in a cantilever shape or may improve durability of the cantilever shape.

Referring to FIGS. 11 and 12, the sensing unit 810 of the Hall sensors 800-51, 800-52, 800-54, 800-61, 800-62, and 800-64 is disposed on the magnetic shield support portion 825 so as to be spaced apart from the first metal layer 120, and a portion of the magnetic shield support portion 825 may be positioned between the magnetic shield 820 and the sensing unit 810. For example, at least a portion of the magnetic shield support portion 825 may be configured as a wiring electrically connecting the sensing unit 810 to the first metal layer 120.

Referring to FIGS. 10 to 12, the Hall sensors 800-43, 800-47, 800-53, 800-57, 800-63, and 800-67 may further include the bonding portion 831 bonding the sensing unit 810 to the magnetic shield support portion 825. For example, the bonding portion 831 may include an adhesive material or an insulating material (which may have weak adhesiveness depending on the design).

Referring to FIGS. 10 to 12, the Hall sensors 800-45, 800-46, 800-55, 800-56, 800-65, and 800-66 may further includes an insulating support portion 832 stacked on the sensing unit 810, and the magnetic shield 820 may be stacked on the insulating support portion 832. For example, the insulating support portion 832 may include an insulating material and may include an adhesive material (e.g., an adhesive polymer, etc.) depending on the design, but is not limited thereto. The stacking (or laminating) may refer to at least one of contact, adhesion, attachment, deposition, and plating between a plurality of components, but is not limited thereto.

The Hall sensors 800-15, 800-25, 800-35, 800-45, 800-55, and 800-65 may further include a sub-substrate 830 disposed between the target pattern of the first metal layer 120 and the sensing unit 810 and electrically connected to the sensing unit 810. For example, the sub-substrate 830 may have a structure in which at least one metal layer and at least one insulating layer are alternately stacked, like a printed circuit board, and may provide an electrical path between the Hall sensor and the first metal layer 120.

For example, the sensing unit 810 may be disposed between the sub-substrate 830 and the insulating support portion 832. The insulating support portion 832 may be disposed between the sensing unit 810 and the magnetic shield 820. In this manner, the Hall sensor may include a structure in which three or more components are sequentially stacked, but is not limited thereto.

The sensing unit 810 of the Hall sensors 800-16, 800-17, 800-26, 800-27, 800-36, 800-37, 800-46, 800-47, 800-56, 800-57, 800-61, 800-62, 800-63, 800-64, 800-66, and 800-67 may include a sensing integrated circuit (IC) 811 configured to sense a magnetic field of the target pattern of the first metal layer 120 and a sensing terminal 812 electrically connecting the sensing IC 811 to the first metal layer 120. For example, the sensing terminal 812 may be implemented as a pin and/or solder of an IC, but is not limited thereto.

The power module for a vehicle including a Hall sensor and a motor driving apparatus including the power module according to at least one example embodiment of the present disclosure may improve sensing accuracy by reducing magnetic field noise when sensing current of the power module and/or reduce energy loss and/or heat generation due to current sensing.

For example, the power module for a vehicle including a Hall sensor and the motor driving apparatus including the power module according to at least one example embodiment of the present disclosure may have a structure for reducing the effective volume and cost of the power module for a vehicle and may embed the Hall sensor in a structure (e.g., a single cooling structure) including (e.g., only) one circuit board.

While embodiments have been shown and described above, it will be apparent to those skilled in the art that modifications and variations could be made without departing from the scope of the present disclosure as defined by the appended claims.

What is claimed is:

1. A power module for a vehicle, the power module comprising:
a circuit board including an insulating layer and a first metal layer;
a switching unit disposed on the circuit board;
a lead frame disposed on a first side of the circuit board;
a signal lead disposed on a second side of the circuit board; and
a Hall sensor arranged on the circuit board,
wherein the Hall sensor includes
a sensing unit disposed to sense a magnetic field of a target pattern of the first metal layer, and
a magnetic shield providing magnetic shielding for at least a portion of a surface of the sensing unit, other than a surface of the sensing unit facing the target pattern.

2. The power module of claim 1, wherein a first portion of the signal lead is electrically connected to the switching unit through a first portion of a signal pattern of the first metal layer, and
a second portion of the signal lead is electrically connected to the Hall sensor through a second portion of the signal pattern of the first metal layer.

3. The power module of claim 2, wherein the Hall sensor further includes a Hall sensor bonding wire electrically connecting the second portion of the signal pattern of the first metal layer to the sensing unit by bypassing the magnetic shield.

4. The power module of claim 3, further comprising:
a switching unit bonding wire electrically connecting a high current pattern of the first metal layer to the switching unit,
wherein the lead frame is electrically connected to the high current pattern of the first metal layer.

5. The power module of claim 1, wherein the first metal layer further includes a high current pattern electrically connected to the lead frame and a signal pattern electrically connected to the signal lead, and
the target pattern of the first metal layer is spaced apart from the high current pattern.

6. The power module of claim 1, wherein at least a portion of the magnetic shield is disposed on the target pattern.

7. The power module of claim 6, wherein the Hall sensor further includes:
an insulating support portion disposed between the target pattern and the magnetic shield; and
a bonding portion bonding the sensing unit to the target pattern.

8. The power module of claim 6, wherein the Hall sensor further includes an insulating support portion arranged between the target pattern and the magnetic shield, and
a portion of the insulating support portion is disposed between the sensing unit and the target pattern.

9. The power module of claim 1, wherein
the Hall sensor further includes an insulating support portion disposed on a pattern, different from the target pattern, in the first metal layer, and
the magnetic shield is disposed on the insulating support portion and does not overlap the sensing unit in a direction in which the sensing unit and the target pattern face each other.

10. The power module of claim 1, wherein
the Hall sensor further includes a sub-substrate disposed between the sensing unit and the magnetic shield and electrically connected to the sensing unit, and
the sub-substrate is supported by a pattern, different from the target pattern, on the first metal layer so that the sensing unit is spaced apart from the target pattern.

11. The power module of claim 1, wherein
the Hall sensor further includes:
a sub-substrate disposed between the sensing unit and the target pattern and electrically connected to the sensing unit; and
a Hall sensor bonding wire electrically connecting a signal pattern of the first metal layer to the sub-substrate.

12. The power module of claim 11, wherein
at least a portion of the magnetic shield is disposed on the sub-substrate, and
the Hall sensor bonding wire is connected to an outside of a region in which the magnetic shield is disposed on the sub-substrate.

13. The power module of claim 12, wherein a combined structure of the magnetic shield and the sub-substrate seals the sensing unit.

14. The power module of claim 1, wherein the magnetic shield surrounds a side surface of the sensing unit,
a lower surface of the sensing unit faces the target pattern, and
the magnetic shield covers an upper surface of the sensing unit.

15. The power module of claim 1, further comprising
a case accommodating the circuit board,
wherein the case has a U-shape open in a direction in which the circuit board faces the sensing unit.

16. The power module of claim 1, further comprising
a case accommodating the circuit board,
wherein the Hall sensor further includes a ground bonding wire electrically connecting the magnetic shield to the case.

17. The power module of claim 16, further comprising
an encapsulant accommodated by the case,
wherein the Hall sensor further includes a Hall sensor bonding wire electrically connecting a signal pattern of the first metal layer to the sensing unit, and
the encapsulant is in direct contact with the circuit board, the magnetic shield, and the Hall sensor bonding wire.

18. The power module of claim 1, wherein
the switching unit includes a first switching unit, a second switching unit, and a third switching unit,
wherein the first switching unit includes a plurality of first semiconductor chips,
the second switching unit includes a plurality of second semiconductor chips, and
the third switching unit includes a third semiconductor chip.

19. The power module of claim 18, wherein
the first switching unit is disposed in a central portion of the circuit board,
the second switching unit is disposed on an outside of the first switching unit on the circuit board, and
the third switching unit is disposed on the outside of the first switching unit on the circuit board.

20. A motor driving apparatus comprising:
a power module for a vehicle, the power module including
a circuit board including an insulating layer and a first metal layer,
a switching unit disposed on the circuit board, the switching unit includes a first switching unit, a second switching unit, and a third switching unit, wherein the first switching unit includes a plurality of first semiconductor chips, the second switching unit includes a plurality of second semiconductor chips, and the third switching unit includes a third semiconductor chip,
a lead frame disposed on a first side of the circuit board,
a signal lead disposed on a second side of the circuit board, and
a Hall sensor arranged on the circuit board,
wherein the Hall sensor includes
a sensing unit disposed to sense a magnetic field of a target pattern of the first metal layer, and
a magnetic shield providing magnetic shielding for at least a portion of a surface of the sensing unit, other than a surface of the sensing unit facing the target pattern,
wherein the power module is a three-phase power module,
wherein, in each phase of the three-phase power module,
the first switching unit includes a 1-1 switching element and a 1-2 switching element and corresponds to a leg of a first inverter,
the second switching unit includes a 2-1 switching element and a 2-2 switching element and corresponds to a leg of a second inverter, and
an end of the third switching unit is connected between a first node between the 1-1 switching element and the 1-2 switching element and a second node between the 2-1 switching element and the 2-2 switching element and is a portion of a changeover switch.
